(19) United States
(12) Patent Application Publication
(10) Pub. No.: US 2019/0163137 A1
(43) Pub. Date: May 30, 2019

(54) ELECTRONIC APPARATUS AND PHOTOELECTRIC CONVERSION DEVICE MANUFACTURING METHOD

(71) Applicant: SEIKO EPSON CORPORATION, Tokyo (JP)

(72) Inventors: Daisuke NAGANO, Matsumoto-shi (JP); Masahiro FURUSAWA, Chino-shi (JP); Maho TERASHIMA, Matsumoto-shi (JP)

(73) Assignee: SEIKO EPSON CORPORATION, Tokyo (JP)

(21) Appl. No.: 16/204,271

(22) Filed: Nov. 29, 2018

(30) Foreign Application Priority Data
Nov. 30, 2017 (JP) 2017-230036

(51) Int. Cl. G04B 19/06; G04G 9/00; H02J 50/30; H01L 21/78; B23K 26/0622; B23K 26/073; B23K 26/364; H01L 31/042

(52) U.S. Cl. CPC G04B 19/065; G04G 9/0064; G04G 9/0076; H02J 50/30; H01L 31/042; B23K 26/0622; B23K 26/0736; B23K 26/364; H01L 21/78

(57) ABSTRACT

An electronic apparatus including a case having an opening including a curve and a photoelectric conversion device that is provided in the case and includes a crystalline semiconductor substrate, the photoelectric conversion having an outer edge that includes at least partially formed of an outer curve portion along the opening, and the photoelectric conversion having an inner edge that includes at least partially formed of an inner curve portion along the outer edge.

### BACKGROUND

1. Technical Field

The present invention relates to an electronic apparatus and a photoelectric conversion device manufacturing method.

2. Related Art

There has been a proposed worn-type electronic apparatus (wristwatch) that receives radio waves from position information satellites used in a positioning system, such as a global positioning system (GPS) and performs a variety of types of operation, such as acquisition of the time contained in a positioning signal and detection of the current position.

For example, JP-A-2016-176957 discloses a wristwatch including a wristwatch case, a dial, a timepiece module including an antenna that is disposed below the dial and receives radio waves from position information satellites, and a solar panel provided between the dial and the timepiece module. According to the thus configured wristwatch, in which the dial has optical transparency, the solar panel irradiated with external light having passed through the dial can generate electric power necessary for the operation of the timepiece module.

On the other hand, a microwave is used as the radio wave transmitted from each of the position information satellites, and a high-frequency circuit needs to operate to receive the microwave. The operation of the high-frequency circuit undesirably increases the electric power consumed by the wristwatch.

In recent years, in particular, it is required to equip the function of recording a movement path of the wristwatch by frequently detecting the current position (data logger). The equipment of such a function increases the period for which the high-frequency circuit operates, and there is therefore a concern about a further increase in the power consumption. In this case, the consumed electric power exceeds the electric power generated by the solar panel, which forces to separately provide a part for allowing an external power supply to charge a secondary battery or needs to increase the capacity of the secondary battery. As a result, reduction in size and weight of the wristwatch cannot be achieved.

On the other hand, in the wristwatch described in JP-A-2016-176957, when external light passes through the dial, the amount of external light undesirably decreases, resulting in a problem of an insufficient amount of electric power generated by the solar panel. To ensure necessary electric power, enlarging the solar panel results in problems of restriction of the size of a primary component, such as the timepiece module, and an increase in the size of the wristwatch.

### SUMMARY

An advantage of some aspects of the invention is to provide an electronic apparatus including a photoelectric conversion device capable of generating sufficient electric power based on photoelectric conversion with the space for a primary component, such as a display section, provided. Another advantage of some aspects of the invention is to provide a photoelectric conversion device manufacturing method that allows efficient manufacture of a photoelectric conversion device suitable for the electronic apparatus.

The advantages described above can be achieved by the following aspects of the invention.

An electronic apparatus according to an aspect of the invention includes a case having an opening including a curve, and a photoelectric conversion device that is provided in the case and includes a crystalline semiconductor substrate. An outer edge of the photoelectric conversion device is at least partially formed of a curve along the opening, and an inner edge of the photoelectric conversion device is at least partially formed of a curve along the outer edge of the photoelectric conversion device.

An electronic apparatus capable of generating sufficient electric power based on photoelectric conversion with the space for a primary component, such as a display section, is thus provided.

In the electronic apparatus according to the aspect of the invention, it is preferable that the photoelectric conversion device includes a plurality of electrode pads, and that the plurality of electrode pads are arranged along the outer or inner edge of the photoelectric conversion device.

The arrangement described above allows connection points to be provided along the direction in which the outer or inner edge of the photoelectric conversion device extends (in circumferential direction). Therefore, the photoelectric conversion device can be more reliably fixed, and the connection resistance between the photoelectric conversion device and a wiring substrate can be sufficiently lowered.

It is preferable that the electronic apparatus according to the aspect of the invention further includes an electrooptical panel having an outer shape along the inner edge of the photoelectric conversion device.

A display section disposed in a region inside the photoelectric conversion device, for example, is therefore allowed to have a circular outer shape, whereby a well-designed electronic apparatus can be achieved.

In the electronic apparatus according to the aspect of the invention, it is preferable that the photoelectric conversion device has an annular shape.

The display section disposed in a region inside the photoelectric conversion device, for example, is therefore allowed to have a circular outer shape, whereby a well-designed electronic apparatus can be achieved.

It is preferable that the electronic apparatus according to the aspect of the invention further includes an electrooptical panel, and that at least part of the photoelectric conversion device is so disposed as to overlap with a region outside a pixel region of the electrooptical panel.

The arrangement described above allows the photoelectric conversion device to function as a so-called parting plate that covers the region outside the pixel region of the electrooptical panel.

In the electronic apparatus according to the aspect of the invention, it is preferable that the semiconductor substrate is a single-crystal semiconductor substrate.

A single-crystal semiconductor substrate allows the photoelectric conversion efficiency of the photoelectric conversion device to be particularly increased. The photoelectric conversion efficiency of the photoelectric conversion device and the exterior design of the electronic apparatus can therefore be both achieved to the highest degree. In particular, the space for the photoelectric conversion device is reduced, whereby the exterior design of the electronic apparatus can be further improved.

In the electronic apparatus according to the aspect of the invention, it is preferable that the photoelectric conversion device includes a plurality of the semiconductor substrates, and that the plurality of the semiconductor substrates have the same crystal orientation.

In this case, since the plurality of semiconductor substrates are likely to have matching exterior appearances, a uniform exterior appearance is achieved, whereby the exterior design of the entire photoelectric conversion device can be further improved. Further, in a case where the light receiving surfaces of the plurality of semiconductor substrates are etched, differences in the etching results naturally decrease in consideration of the fact that the etching rate tends to depend on the crystal orientation. Also from this viewpoint, the light receiving surfaces of the plurality of semiconductor substrates are likely to have matching characteristics, such as the optical reflectance and reflection direction, whereby the exterior design of the entire photoelectric conversion device can be further improved.

In the electronic apparatus according to the aspect of the invention, it is preferable that a concentration of an impurity element other than a primary constituent element of the semiconductor substrate is lower than or equal to 1×10¹¹ [atoms/cm²].

The thus set concentration can sufficiently suppress the effect of the impurity in the semiconductor substrate on the photoelectric conversion. As a result, a photoelectric conversion device having a small area but capable of generating sufficient electric power can be achieved.

In the electronic apparatus according to the aspect of the invention, it is preferable that two perpendiculars passing through two different points on the inner edge of the photoelectric conversion device intersect each other in the opening.

The inner edge of the photoelectric conversion device therefore has satisfactory curvature that allows a more sufficient space to be provided inside the opening. The display section and the photoelectric conversion device are therefore arranged in a better-balanced manner.

In the electronic apparatus according to the aspect of the invention, it is preferable that at least part of an end surface of the photoelectric conversion device is so configured that a light receiving surface overhangs beyond a rear surface.

As a result, when the photoelectric conversion device is viewed from the side facing the light receiving surfaces, the end surface is unlikely to be visible behind the overhanging light receiving surface. The light receiving surface therefore forms a visually dominant portion, whereby the uniformity of the exterior appearance of the photoelectric conversion device is increased. The exterior design of the photoelectric conversion device and the electronic timepiece can therefore be further improved.

In the electronic apparatus according to the aspect of the invention, it is preferable that the photoelectric conversion device is a rear-surface-electrode-type photoelectric conversion device.

The rear-surface-electrode-type photoelectric conversion device allows all electrode pads to be disposed on an electrode surface (rear surface). The light receiving surface can therefore be maximized, whereby the electric power generation efficiency can be improved in accordance with the maximization of the light receiving area. In addition, degradation in the exterior design due to the electrode pads provided on the light receiving surface can be avoided. The exterior design of the electronic apparatus can therefore be further improved.

A photoelectric conversion device manufacturing method according to another aspect of the invention includes preparing a crystalline semiconductor wafer, forming electrodes and electrode pads on the semiconductor wafer, and performing laser processing on the semiconductor wafer to cut a cell having an outer edge at least partially formed of a curve and an inner edge at least partially formed of a curve along the outer edge.

A cell suitable for the electronic apparatus can thus be efficiently manufactured.

In the photoelectric conversion device manufacturing method according to the aspect of the invention, it is preferable that a surface of the semiconductor wafer that is the surface on which the electrode pads have been formed is irradiated with a laser beam for the laser processing.

The laser processing forms an inclining surface that inclines in such a way that the surface that forms the light receiving surface overhangs beyond the surface on which the electrode pads have been formed and which is opposite the light receiving surface.

### BRIEF DESCRIPTION OF THE DRAWINGS

The invention will be described with reference to the accompanying drawings, wherein like numbers reference like elements.

FIG. 1 is a perspective view showing an electronic timepiece using an electronic apparatus according to an embodiment of the invention.

FIG. 2 is another perspective view showing the electronic timepiece using the electronic apparatus according to the embodiment of the invention.

FIG. 3 is a plan view of the electronic timepiece shown in FIGS. 1 and 2.

FIG. 4 is a longitudinal cross-sectional view of the electronic timepiece shown in FIGS. 1 and 2.

FIG. 5 is a plan view showing only photoelectric conversion devices out of the components of the electronic timepiece shown in FIG. 4.

FIG. 6 is an exploded perspective view of the photoelectric conversion devices shown in FIG. 5.

FIG. 7 is a cross-sectional view of the photoelectric conversion devices shown in FIG. 5 taken along the line A-A.

FIG. 8 describes a photoelectric conversion device manufacturing method according to an embodiment of the invention.

FIG. 9 describes the photoelectric conversion device manufacturing method according to the embodiment of the invention.

FIG. 10 describes the photoelectric conversion device manufacturing method according to the embodiment of the invention.

FIG. 11 describes the photoelectric conversion device manufacturing method according to the embodiment of the invention.

FIG. 12 describes the photoelectric conversion device manufacturing method according to the embodiment of the invention.

FIG. 13 describes the photoelectric conversion device manufacturing method according to the embodiment of the invention.

FIG. 14 describes the photoelectric conversion device manufacturing method according to the embodiment of the invention.

### DESCRIPTION OF EXEMPLARY EMBODIMENTS

An electronic apparatus and a photoelectric conversion device manufacturing method according to preferable embodiments of the invention will be described below in detail with reference to the accompanying drawings.

### Electronic Apparatus

An electronic timepiece using the electronic apparatus according to the embodiment of the invention will first be described. The electronic timepiece is so configured that a built-in solar cell (photoelectric conversion module) generates electric power (photoelectric conversion) when a light receiving surface is irradiated with light and the electric power produced by the electric power generation is used as drive electric power.

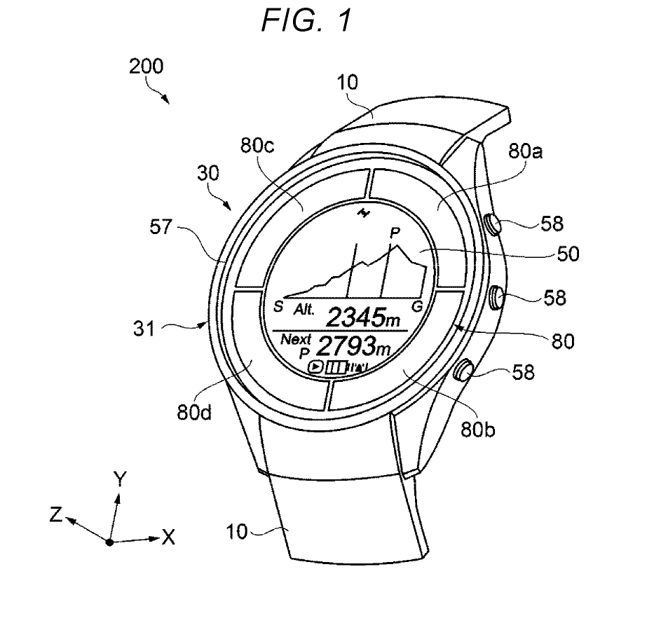

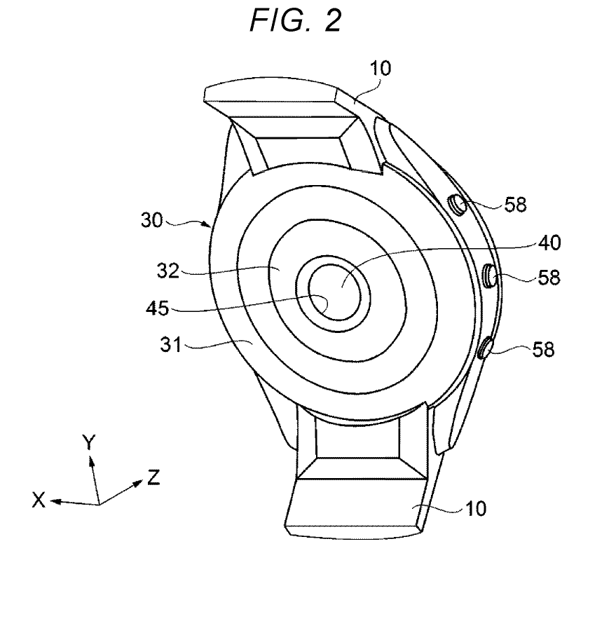

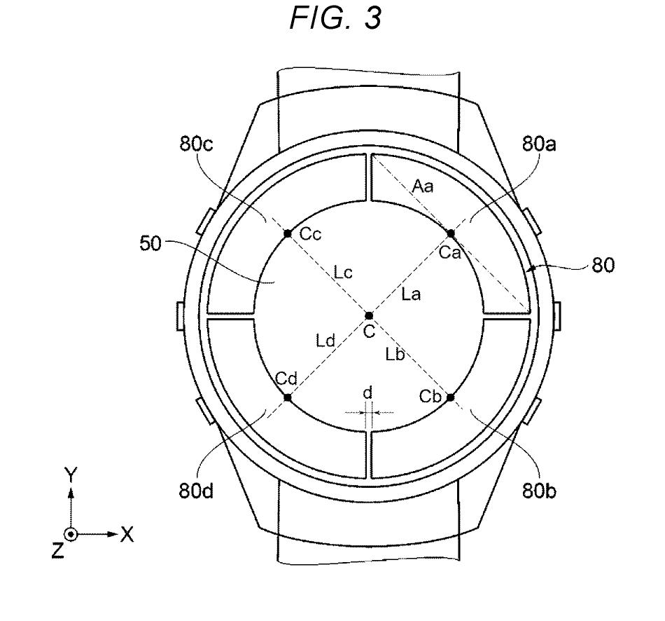

FIGS. 1 and 2 are perspective views showing the electronic timepiece using the electronic apparatus according to the embodiment of the invention. FIG. 1 is a perspective view showing the exterior appearance of the electronic timepiece viewed from the side facing the front side thereof (side facing light receiving surface). FIG. 2 is a perspective view showing the exterior appearance of the electronic timepiece viewed from the side facing the rear side thereof. FIG. 3 is a plan view of the electronic timepiece shown in FIGS. 1 and 2, and FIG. 4 is a longitudinal cross-sectional view of the electronic timepiece shown in FIGS. 1 and 2.

An electronic timepiece 200 includes a timepiece main body 30, which includes a case 31, a solar cell 80 (photoelectric conversion module), a display section 50, and an optical sensor section 40, and two bands 10 attached to the case 31.

In the following description, the directional axis extending in the direction perpendicular to the light receiving surface of the solar cell 80 is called a Z axis. Further, the orientation from the rear side toward the front side of the electronic timepiece is called a “+Z direction,” and the direction opposite the +Z direction is called a “−Z direction.”

On the other hand, two axes perpendicular to the Z axis is called an “X axis” and a “Y axis.” The Y axis is the directional axis that connects the two band 10 to each other, and the X axis is the directional axis perpendicular to the Y axis. The upward direction with respect to the display section 50 is called a “+Y direction,” and the downward direction with respect to the display section 50 is called a “−Y direction.” In the plan view of the light receiving surface of the solar cell 80, the rightward direction is called a “+X direction,” and the leftward direction is called a “−X direction.”

The configuration of the electronic timepiece 200 will be sequentially described below.

### Timepiece Main Body

The timepiece main body 30 includes an enclosure formed of the case 31, which opens frontward and rearward, a windshield 55, which is so provided as to close the front opening, a bezel 57, which is so provided as to cover the front surface of the case 31 and the side surface of the windshield 55, and a transparent cover 44, which is so provided as to close the rear opening. A variety of components that will be described later are accommodated in the enclosure.

Out of the components that form the enclosure, the case 31 has an annular shape and includes a front opening 35, into which the windshield 55 can be fit, and a rear opening (measurement window 45) to which the transparent cover 44 can be fit.

Part of the rear side of the case 31 forms a convex section 32, which is so formed as to protrude. A top portion of the convex section 32 opens, and the transparent cover 44 is fit into the opening with part of the transparent cover 44 protruding beyond the opening.

Examples of the material of which the case 31 is made may include stainless steel, a titanium alloy, or any other metal material, a resin material, and a ceramic material. The case 31 maybe an assembly of a plurality of portions. In this case, the portions may be made of different materials.

A plurality of operation sections 58 (operation buttons) are provided on the outer side surface of the case 31.

A protruding section 34, which protrudes in the +Z direction, is formed along the outer edge of the opening 35 provided on the front side of the case 31. The annular bezel 57 is so provided as to cover the protruding section 34.

Further, the windshield 55 is provided in the region inside the bezel 57. The side surface of the windshield 55 and the bezel 57 are bonded to each other via a bonding member 56, such as a gasket or an adhesive.

Examples of the materials of which the windshield 55 and the transparent cover 44 are made may include a glass material, a ceramic material, and a resin material. The windshield 55 has optical transparency and allows visual recognition of a content displayed by the display section 50 through the windshield 55. Further, the transparent cover 44 also has optical transparency and allows the photosensor section 40 to function as a biological information measurement section.

An internal space 36 in the enclosure is a closed space that can accommodate a variety of components that will be described later.

The timepiece main body 30 includes, as elements accommodated in the internal space 36, a circuit substrate 20, an orientation sensor 22 (geomagnetism sensor), an acceleration sensor 23, a GPS antenna 28, the photosensor section 40, an electrooptical panel 60 and an illuminator 61, which form the display section 50, a secondary battery 70, and the solar cell 80. The timepiece main body 30 may further include, as well as the elements describe above, a pressure sensor for calculating the altitude, the water depth, and other physical quantities, a temperature sensor for measuring the temperature, an angular velocity sensor, and a variety of other sensors, and a vibrator.

The circuit substrate 20 is a substrate including wiring lines that electrically connect the elements described above to each other. On the circuit substrate 20 are mounted a CPU 21 (central processing unit), which includes a control circuit that controls the action of each of the elements described above, a drive circuit, and other circuits, and other circuit devices 24.

The solar cell 80, the electrooptical panel 60, the circuit substrate 20, and the optical sensor section 40 are arranged in the presented order from the side facing the windshield 55. Therefore, the solar cell 80 is disposed in the vicinity of the windshield 55, and a large amount of external light is efficiently incident on the solar cell 80. As a result, the electric power generation efficiency of the solar cell 80 can be maximized.

The elements accommodated in the timepiece main body 30 will be described below in more details.

The circuit substrate 20 has an end portion attached to the case 31 via a circuit case 75.

A connection wiring section 63 and a connection wiring section 81 are electrically connected to the circuit substrate 20. The circuit substrate 20 is electrically connected to the electrooptical panel 60 via the connection wiring section 63. The circuit substrate 20 is electrically connected to the solar cell 80 via the connection wiring section 81. The connection wiring sections 63 and 81 are each formed, for example, of a flexible circuit substrate and efficiently routed through spaces in the internal space 36.

The orientation sensor 22 and the acceleration sensor 23 can detect information on the motion of a user who wears the electronic timepiece 200. The orientation sensor 22 and the acceleration sensor 23 each output a signal that changes in accordance with the user's body motion and transmits the signal to the CPU 21.

The CPU 21 includes a circuit that controls a GPS reception section (not shown) including the GPS antenna 28, a circuit that drives the optical sensor section 40 to measure the user's pulse wave and other pieces of user's biological information, a circuit that drives the display section 50, a circuit that controls the electric power generation performed by the solar cell 80, and other circuits.

The GPS antenna 28 receives radio waves from a plurality of position information satellites. The timepiece main body 30 includes a signal processor that is not shown. The signal processor performs positioning calculation based on a plurality of positioning signals received via the GPS antenna 28 to acquire time and position information. The signal processor transmits the acquired information to the CPU 21.

The optical sensor section 40 is a biological information measurement section that detects the user's pulse wave and other pieces of biological information. The optical sensor section 40 shown in FIG. 2 is a photoelectric sensor including a light receiver 41, a plurality of light emitters 42 provided in a region outside the light receiver 41, and a sensor substrate 43, on which the light receiver 41 and the light emitters 42 are mounted. The light receiver 41 and the light emitters 42 face the measurement window 45 of the case 31 via the transparent cover 44 described above. The circuit substrate 20 is electrically connected to the optical sensor section 40 via a connection wring section 46 provided in the timepiece main body 30.

The thus configured optical sensor section 40 detects the pulse wave when a subject (user's skin, for example) is irradiated with light emitted from the light emitters 42 and the light receiver 41 receives the light reflected off the subject. The optical sensor section 40 transmits information on the detected pulse wave to the CPU 21.

The photoelectric sensor may be replaced with an electrocardiograph, an ultrasonic sensor, or any other sensor.

The timepiece main body 30 further includes a communication section that is not shown. The communication section transmits a variety of pieces of information acquired by the timepiece main body 30, information stored in the timepiece main body 30, results of computation performed by the CPU 21, and other pieces of information to an external apparatus.

The display section 50 allows the user to visually recognize a content displayed on the electrooptical panel 60 through the windshield 55. The thus configured display section 50 displays, for example, information acquired from any of the elements described above in the form of letters or an image to allow the user to recognize the information.

Examples of the electrooptical panel 60 may include a liquid crystal display device, an organic electro luminescence (EL) display device, an electrophoresis display device, and an LED (light emitting diode) display device.

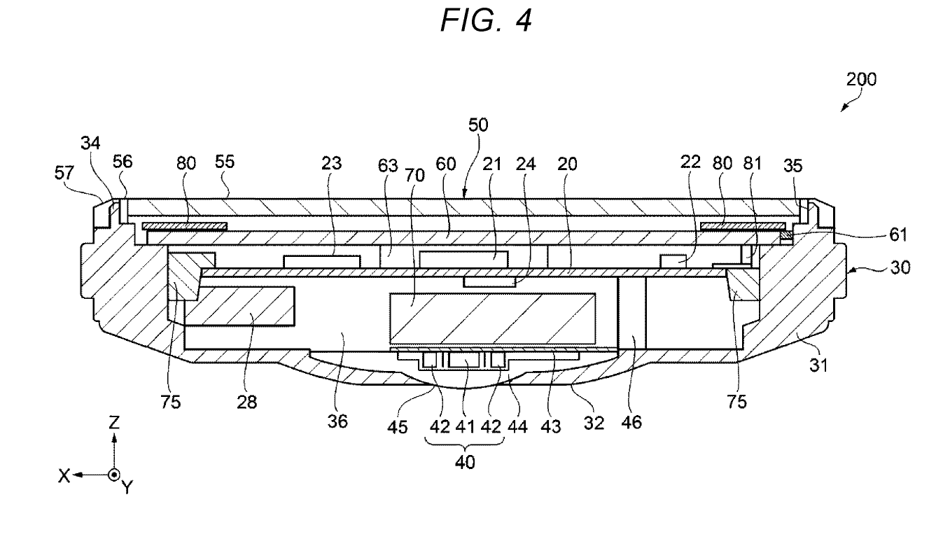

FIG. 4 shows a case where the electrooptical panel 60 is a reflective display device (reflective liquid crystal display device or electrophoresis display device, for example) by way of example. The display section 50 therefore includes the illuminator 61, which is so provided as to face a light incident surface of a light guide plate (not shown) provided in the electrooptical panel 60. The illuminator 61 may, for example, be an LED device. The illuminator 61 and the light guide plate function as a front light for the reflective display device.

In a case where the electrooptical panel 60 is a transmissive display device (transmissive liquid crystal display device, for example), the front light may be replaced with a backlight.

In a case where the electrooptical panel 60 is a self-luminous display device (organic EL display device or LED display device, for example) or a case where the electrooptical panel 60 is a display device that is not a self-luminous display device but uses external light, no front light or backlight need to be provided.

The secondary battery 70 is connected to the circuit substrate 20 via wiring lines that are not shown. The electric power outputted from the secondary battery 70 can therefore be used to drive the elements described above. The electric power generated by the solar cell 80 can charge the secondary battery 70.

The electronic timepiece 200 has been described above, but the electronic apparatus according to the embodiment of the invention is not limited to an electronic timepiece and may instead, for example, be a mobile phone terminal, a smartphone, a tablet terminal, a wearable terminal, or a camera.

### Solar Cell

The solar cell 80 is a photoelectric conversion module that converts optical energy into electrical energy.

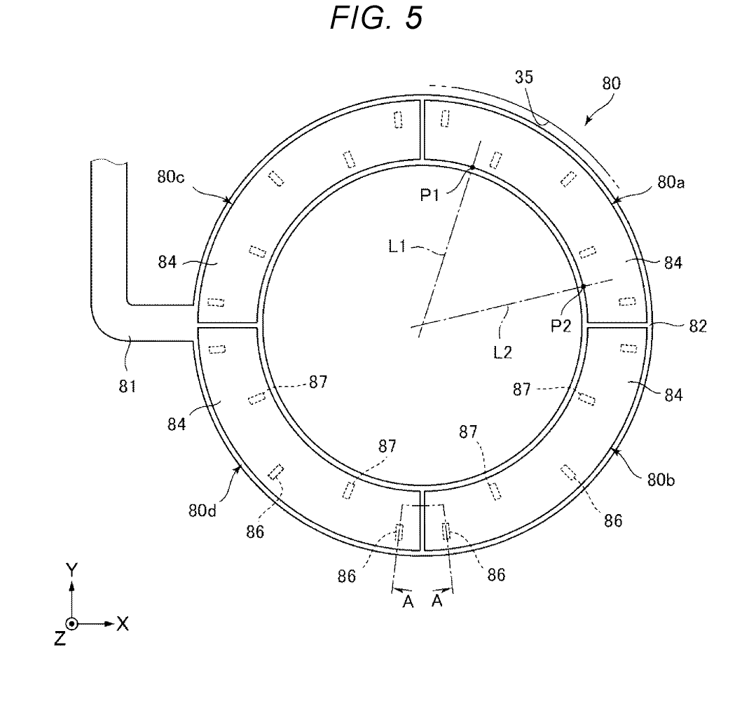

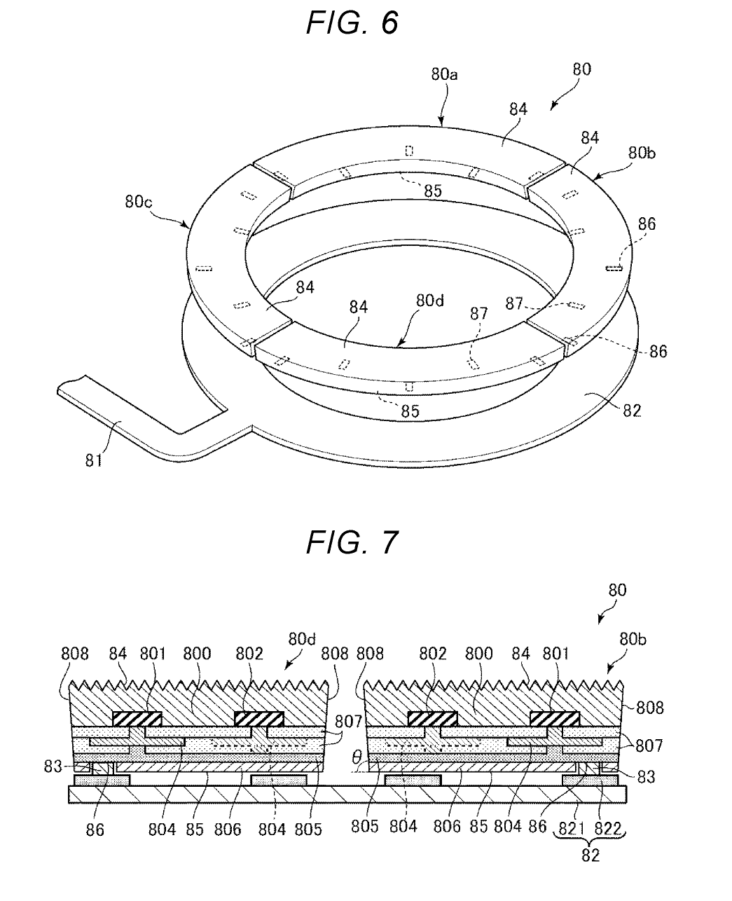

FIG. 5 is a plan view showing only the solar cell 80 out of the components of the electronic timepiece 200 shown in FIG. 4. FIG. 6 is an exploded perspective view of the solar cell 80 shown in FIG. 5.

The solar cell 80 (photoelectric conversion module) shown in FIG. 5 includes four cells 80a, 80b, 80c, and 80d (photoelectric conversion devices), which are provided between the windshield 55 and the electrooptical panel 60 and each formed of a crystalline semiconductor substrate, and a wiring substrate 82, which is electrically connected to the four cells 80a, 80b, 80c, and 80d.

The cells 80a, 80b, 80c, and 80d each have a plate-like shape having principal surfaces oriented in the Z-axis direction. The principal surface facing the windshield 55 forms a light receiving surface 84, which receives external light. On the other hand, the principal surface facing the electrooptical panel 60 forms an electrode surface 85, on which electrode pads via which the generated electric power is extracted are provided.

The solar cell 80 shown in FIG. 5 has an annular shape. In other words, the four cells 80a, 80b, 80c, and 80d arranged with slight gaps therebetween forms an annular shape having a circular inner edge shape (inner shape) and a circular outer edge shape (outer shape).

On the other hand, the opening 35 of the case 31 described above has a circular shape, and the inner edge of the opening 35 therefore includes a curve.

That is, the electronic timepiece 200 (electronic apparatus) includes the case 31, which has the opening 35 including a curved contour, and the solar cell 80, which is provided in the case 31 and includes a crystalline semiconductor substrate.

The outer edge of the solar cell 80 extends along the opening 35 and therefore has a circular shape. That is, the outer edge of the solar cell 80 is at least partially formed of a curve (an outer curve portion) along the opening 35.

The inner edge of the solar cell 80 extends along the outer edge of the solar cell 80 and therefore has a circular shape. That is, the inner edge of the solar cell 80 is at least partially formed of a curve (an inner curve portion) along the outer edge of the solar cell 80.

According to the thus configured electronic timepiece 200, the solar cell 80 can be efficiently disposed in the case 31 having the circular opening 35 with the space for a primary component, such as the display section 50, provided. Since the solar cell 80 can therefore be disposed in the vicinity of the windshield 55, the solar cell 80 can generate electric power with sufficient efficiency. On the other hand, since the space where the display section 50 is disposed can be provided at a central portion of the opening 35, the visibility of the display section 50 increases, and the display section 50 and the solar cell 80 are arranged in a well-balanced manner. As a result, the electronic timepiece 200 excels both in the electric power generation efficiency of the solar cell 80 and the overall exterior design of the timepiece.

The (inner edge of the) opening 35 of the case 31 only needs to at least partially have a curve and may include, for example, a straight line and a curve.

The phrase “the outer edge of the solar cell 80” refers to, out of the contour of the solar cell 80, the portion that faces the outer side of the opening 35, and the phrase “the inner edge of the solar cell 80” refers to, out of the contour of the solar cell 80, the portion that faces the center of the opening 35.

The sentence “the outer edge of the solar cell 80 extends along the opening 35” refers to a state in which the outer edge of the solar cell 80 and the inner edge of the opening 35 extend with the distance therebetween maintained at a fixed value. The phrase “the distance maintained at a fixed value” refers to a state in which the magnitude of change in the separation distance between the outer edge of the solar cell 80 and the inner edge of the opening 35 is smaller than or equal to 100% of the maximum separation distance (preferably smaller than or equal to 10% of the average of the separation distances) over the total length of the outer edge of the solar cell 80.

The sentence “the inner edge of the solar cell 80 extends along the outer edge of the solar cell 80” refers to a state in which the outer edge of the solar cell 80 and the inner edge of the solar cell 80 extend with the distance therebetween maintained at a fixed value. The phrase “the distance maintained at a fixed value” refers to a state in which the magnitude of change in the separation distance between the inner edge of the solar cell 80 and the outer edge of the solar cell 80 is smaller than or equal to 100% of the maximum separation distance (preferably smaller than or equal to 10% of the average of the separation distances) over the total length of the inner edge of the solar cell 80.

Assume that perpendiculars L1 and L2 passing through two different points P1 and P2 on the inner edge of the solar cell 80 are drawn, that is, assume that straight lines perpendicular to the inner edge are so drawn as to pass through two different points on the inner edge, and the two perpendiculars L1 and L2 preferably intersect each other in the opening 35, as shown in FIG. 5. In the case where the condition described above is satisfied, the inner edge of the solar cell 80 has satisfactory curvature that allows a more sufficient space to be provided inside the opening 35. The display section 50 and the solar cell 80 are therefore arranged in a better-balanced manner.

The inner and outer edges of each of the four cells 80a, 80b, 80c, and 80d are preferably part of circles having the same center (concentric circles). In other words, the assembly of the four cells 80a, 80b, 80c, and 80d has an annular shape, the inner and outer circles of the annular shape are preferably concentric circles. A particularly well-designed electronic timepiece 200 can thus be achieved.

The display section 50 (electrooptical panel 60) is provided in a region inside the inner edge of the solar cell 80, and the outer shape of the display section 50 follows the inner edge of the solar cell 80, as shown in FIG. 3. In other words, the electronic timepiece 200 includes an electrooptical panel 60 having an outer shape that follows the inner edge of the solar cell 80. The arrangement described above allows, for example, a circular outer shape of the display section 50 disposed in a region inside the solar cell 80, whereby a well-designed electronic timepiece 200 can be achieved.

At least part of the solar cell 80 is so disposed as to overlap with the region outside the pixel region of the electrooptical panel 60. As a result, for example, in the view of the electronic timepiece 200 in which the light receiving surfaces 84 of the solar cell 80 is squarely viewed, disposing the display section 50 (electrooptical panel 60) in a position separate from the solar cell 80 allows the solar cell 80 to function as a so-called parting plate that covers the region outside the pixel region of the electrooptical panel 60.

Further, in the present embodiment, the assembly of the four cells 80a, 80b, 80c, and 80d forms the solar cell 80. The number of cells may instead be one, two or more, or any other arbitrary number.

In the present embodiment, the solar cell 80 has an annular shape. The solar cell 80 may instead be formed of a plurality of annular shapes.

Out of the four cells 80a, 80b, 80c, and 80d, at least one of them may be omitted, and the cells may have shapes different from one another.

The semiconductor substrate that forms the solar cell 80 is a crystalline semiconductor substrate, as described above. A crystalline semiconductor substrate refers to a single-crystal semiconductor substrate or a polycrystal semiconductor substrate. A crystalline semiconductor substrate allows the solar cell 80 to have higher electric power generation efficiency than in a case where the solar cell 80 is formed of an amorphous semiconductor substrate. To generate a fixed amount of electric power, the solar cell 80 formed of a crystalline semiconductor substrate allows the area thereof to decrease. A crystalline semiconductor substrate therefore allows the electronic timepiece 200 to excel both in the electric power generation efficiency and the exterior design to a high degree.

A single-crystal semiconductor substrate is particularly preferable because the electric power generation efficiency of the solar cell 80 can be particularly increased. The electric power generation efficiency and the exterior design can therefore be both achieved to the highest degree. In particular, the space for the solar cell 80 is reduced, whereby the exterior design of the electronic timepiece 200 can be further improved. Further, as another advantage, the electric power generation efficiency is unlikely to decrease even under low-illuminance light, such as room light.

The case where a single-crystal semiconductor substrate is used includes not only a case where the entire semiconductor substrate is a single-crystal semiconductor substrate but a case where part of the semiconductor substrate is polycrystal or amorphous semiconductor substrate. In the latter case, the single-crystal portion preferably has a relatively large volume (at least 90 vol %, for example).

Examples of the semiconductor substrate may include not only a silicon substrate, for example, but a compound semiconductor substrate (GaAs substrate, for example).

In a case where the solar cell 80 includes the four cells 80a, 80b, 80c, and 80d (a plurality of semiconductor substrates) and the semiconductor substrates are each a single-crystal semiconductor substrate, the principal surfaces of the four cells 80a, 80b, 80c, and 80d preferably have the same crystal orientation (crystal axis). In this case, since the four cells 80a, 80b, 80c, and 80d are likely to have matching exterior appearances, a uniform exterior appearance is achieved, whereby the exterior design of the entire solar cell 80 can be further improved. Further, in a case where the light receiving surfaces of the four cells 80a, 80b, 80c, and 80d are etched, differences in the etching results naturally decrease in consideration of the fact that the etching rate tends to depend on the crystal orientation. Also from this viewpoint, the light receiving surfaces of the four cells 80a, 80b, 80c, and 80d are likely to have matching characteristics, such as the optical reflectance and reflection direction, whereby the exterior design of the entire solar cell 80 can be further improved.

Further, in the case where the four cells 80a, 80b, 80c, and 80d are arranged in an annular shape as a whole, as shown in FIG. 3, let La, Lb, Lc, and Ld be imaginary straight lines extending from the center C of the annular shape toward the centers Ca, Cb, Cc, and Cd of the cells.

It is then preferable that the crystal orientation parallel to the imaginary line La out of the crystal orientations of the cell 80a, the crystal orientation parallel to the imaginary line Lb out of the crystal orientations of the cell 80b, the crystal orientation parallel to the imaginary line Lc out of the crystal orientations of the cell 80c, and the crystal orientation parallel to the imaginary line Ld out of the crystal orientations of the cell 80d are preferably equivalent to one another. The above-mentioned exterior design of the solar cell 80 can thus be further improved. That is, in the case where the light receiving surfaces of the four cells 80a, 80b, 80c, and 80d are etched, and even when etching anisotropy based on the crystal orientation occurs in each of the light receiving surfaces, the anisotropies are rotationally symmetric with respect to the center C of the annular shape described above, which serves as the axis of rotation of the symmetry. The effect of the etching anisotropies having occurred in the four cells 80a, 80b, 80c, and 80d on the exterior design of the entire solar cell 80 can therefore be minimized.

The center C of the annular shape refers to the center of the annular shape formed of the assembly of the four cells 80a, 80b, 80c, and 80d. From the exterior design point of view, the center C preferably coincides with the center of the opening 35 of the case 31.

The center of each of the cells refers to the midpoint of the major axis of the cell. For example, in the case of the cell 80a, and assuming that the possible longest line segment is the major axis Aa (see FIG. 3), the midpoint of the major axis Aa is the center Ca of the cell 80a.

The phrase “equivalent to one another” refers to a state in which the above-mentioned crystal orientations of the cells 80a, 80b, 80c, and 80d can be considered to be the same in hexagonal single-crystal silicon. Specifically, for example, since the [110] axis, the [101] axis, the [011] axis, the [1-10] axis, the [10-1] axis, and the [01-1] axis of single-crystal silicon are not distinguished from one another in crystallography, these axes are collectively called a <110> axis and considered as axes equivalent to one another. Therefore, when the above-mentioned crystal orientations of the cells 80a, 80b, 80c, and 80d are each the <110> axis, that is, any of the six axes described above, it can be said that the crystal orientations are equivalent to one another.

The solar cell 80 is preferably a rear-surface-electrode-type solar cell. Specifically, the electrode surface 85 of each of the four cells 80a, 80b, 80c, and 80d is provided with electrode pads 86 and 87, as shown in FIG. 6. The electrode pad 86 is the anode, and the electrode pad 87 is the cathode. Electric power can therefore be extracted from the electrode pads 86 and 87 via wiring lines.

The rear-surface-electrode-type solar cell allows all the electrode pads to be disposed on the electrode surfaces (rear surfaces). The light receiving surfaces 84 can therefore each be maximized, whereby the electric power generation efficiency can be improved in accordance with the maximization of the light receiving areas. In addition, degradation in the exterior design due to the electrode pads provided on the light receiving surfaces 84 can be avoided. The exterior design of the electronic timepiece 200 can therefore be further improved.

The solar cell 80 preferably includes a plurality of electrode pads 86 and electrode pads 87, as shown in FIG. 5. The cells 80a, 80b, 80c, and 80d can thus be electrically and mechanically connected to the wiring substrate 82 in a more reliable manner.

The plurality of electrode pads 86 are arranged along the outer edge of the solar cell 80. On the other hand, the plurality of electrode pads 87 are arranged along the inner edge of the solar cell 80. The arrangement described above allows connection points to be provided along the direction in which the solar cell 80 extends (in circumferential direction). Therefore, the solar cell 80 can be more reliably fixed, and the connection resistance between the solar cell 80 and the wiring substrate 82 can be sufficiently lowered.

The arrangement of the electrode pads 86 and 87 are not limited to that shown in FIG. 5. For example, the position of the row of the electrode pads 86 and the position of the row of the electrode pads 87 may be swapped with each other.

The number of electrode pads 86 and 87 per cell is not limited to a specific number and may be one or any arbitrary number greater than one. Further, the shape of the electrode pads 86 and 87 is not limited to a specific shape and may be any shape.

FIG. 7 is a cross-sectional view of the solar cell 80 shown in FIG. 5 taken along the line A-A. FIG. 7 shows a case where an Si substrate 800 is used as the semiconductor substrate.

The solar cell 80 shown in FIG. 7 includes the Si substrate 800, p+ diffused regions 801 and n+ diffused regions 802 formed in the Si substrate 800, finger electrodes 804 connected to the p+ diffused regions 801 and the n+ diffused regions 802, and a bus bar electrode 805 connected to the finger electrodes 804. FIG. 7 shows only the bus bar electrode 805 and the electrode pads 86 (anodes) connected to the p+ diffused regions 801 but does not show the bus bar electrode and the electrode pads (cathodes) connected to the n+ diffused regions 802 for ease of illustration. Further, in FIG. 7, the finger electrodes 804 connected to the n+ diffused regions 802 are drawn by the broken lines, which indicates that these finger electrodes 804 are not electrically connected to the bas bar electrode 805.

The Si substrate 800 is, for example, an Si(100) substrate. The crystal plane of the Si substrate 800 is not limited to a specific plane and may differ from the Si(100) plane.

The concentration of each impurity element other than the primary constituent element of the Si substrate 800 (semiconductor substrate) is preferably as low as possible. For example, the concentration of each impurity element other than the primary constituent element of the Si substrate 800 (semiconductor substrate) is preferably lower than or equal to 1×10¹¹ [atoms/cm²], more preferably lower than or equal to 1×10¹⁰ [atoms/cm²]. The concentration of each impurity element that falls within any of the ranges described above can sufficiently suppress the effect of the impurity in the Si substrate 800 on the photoelectric conversion. As a result, a solar cell 80 having a small area but capable of generating sufficient electric power can be achieved. Further, as another advantage, the electric power generation efficiency is unlikely to decrease even under low-illuminance light, such as room light.

The concentrations of an impurity element in the Si substrate 800 can be measured, for example, by using inductively coupled plasma-mass spectrometry (ICP-MS method).

Part of the bus bar electrode 805 connected to the p+ diffused regions 801 is exposed to form the electrode pads 86 described above. On the other hand, part of the bus bar electrode 805 (not shown) connected to the n+ diffused regions 802 is exposed to form the electrode pads 87 described above.

The electrode pads 86 are each connected to the wiring substrate 82 via an electrically conductive connection section 83, as shown in FIG. 7. Similarly, the electrode pads 87 are each connected to the wiring substrate 82 via an electrically conductive connection section that is not shown.

Examples of each of the electrically conductive connection sections 83 may include electrically conductive paste, an electrically conductive sheet, a metal material, solder, and a brazing material.

Texture is formed on the light receiving surfaces 84 of the Si substrate 800. The texture is formed, for example, of a large number of pyramidal protrusions formed on the light receiving surfaces 84. Providing the texture suppresses reflection of external light off the light receiving surfaces 84, whereby the amount of light incident on the Si substrate 800 can be increased.

In the case where the Si substrate 800 is, for example, a substrate the principal surface of which is the Si(100) plane, pyramidal protrusions having inclining surfaces formed of the Si(111) plane are preferably used as the texture.

The solar cell 80 further includes passivation films that are not shown but are provided on the light receiving surfaces 84. The passivation films may each function as an antireflection film. On the other hand, the solar cell 80 includes passivation films 806 provided on the electrode surfaces 85.

The finger electrodes 804 and the Si substrate 800 are insulated from each other via an interlayer insulating film 807, and so are the bus bar electrode 805 and the finger electrodes 804.

Examples of the materials of which the passivation films 806 and the interlayer insulating film 807 are made may include silicon oxide, silicon nitride, silicon oxynitride, and aluminum oxide.

Examples of the materials of which the finger electrodes 804 and the bus bar electrode 805 are made may include aluminum, titanium, copper, or any other single metal or an alloy thereof.

The wiring substrate 82 includes an insulating substrate 821 and electrically conductive films 822 provided thereon.

Examples of the insulating substrate 821 may include a polyimide substrate, a polyethylene terephthalate substrate, or any of a variety of other resin substrates. Examples of the material of which the electrically conductive films 822 are made may include copper or a copper alloy, aluminum or an aluminum alloy, or silver or a silver alloy.

End surfaces 808 of the solar cell 80 preferably incline with respect to the electrode surfaces 85 (rear surfaces), as shown in FIG. 7. Specifically, the end surfaces 808 preferably incline in such a way that the light receiving surfaces 84 overhang beyond the electrode surfaces 85 (rear surfaces). As a result, when the solar cell 80 is viewed from the side facing the light receiving surfaces 84, the end surfaces 808 are unlikely to be visible behind the overhanging light receiving surfaces 84. The light receiving surfaces 84 therefore form a visually dominant portion, whereby the uniformity of the exterior appearance of the solar cell 80 is increased. The exterior design of the solar cell 80 and the electronic timepiece 200 can therefore be further improved.

In other words, if the end surfaces 808 are visible, a color, a pattern, and optical reflectance different from those of the light receiving surfaces 84 are visually recognized, possibly resulting in degradation in the exterior appearance of the solar cell 80.

The entire end surfaces 808 preferably have the inclination described above, but part of the end surfaces 808 may instead have the inclination. In the latter case, at least the inner edge of the solar cell 80 preferably has the inclination. As a result, degradation in the exterior appearance of the display section can be suppressed when the display section 50 is visually recognized.

The inclination angle θ of the end surfaces 808 is not limited to a specific value as long as it is smaller than 90°, but preferably greater than or equal to 45° but smaller than 90°, more preferably greater than or equal to 60° but smaller than or equal to 85°, still further preferably greater than or equal to 70° but smaller than or equal to 80°. The thus set inclination angle θ causes the end surfaces 808 to be unlikely to be visible even when the viewpoint is changed and prevents a decrease in the electric power generation efficiency and degradation in the mechanical characteristics of the solar cell 80. That is, when the inclination angle θ is smaller than the lower limit described above, the area of each of the electrode surfaces 85 decreases accordingly, undesirably resulting in a decrease in the electric power generation efficiency and degradation in the mechanical characteristics.

Among the angles between each of the electrode surfaces 85 (rear surfaces) and the corresponding end surface 808, the inclination angle θ of the end surface 808 refers to the angle formed at the outer side of the cell.

The length d (see FIG. 3) of the gap between the cells 80a, 80b, 80c, and 80d is not limited to a specific value but is preferably greater than or equal to 0.05 mm but smaller than or equal to 3 mm, more preferably greater than or equal to 0.1 mm but smaller than or equal to 1 mm. Setting the length d of each of the gaps to fall within any of the ranges described above allows the end surfaces 808 shown in FIG. 7 to be less visible when the solar cell 80 is viewed from the side facing the light receiving surfaces 84. Further, the thus set length d of each of the gaps is useful also from the viewpoint of avoidance of problems of difficulty in the assembly of the solar cell 80 and possibility of contact between the cells that occur when the length d is too short.

The thickness of each of the cells 80a, 80b, 80c, and 80d is not limited to a specific value but is preferably greater than or equal to 50 μm but smaller than or equal to 500 μm, more preferably greater than or equal to 100 μm but smaller than or equal to 300 μm. The thus set thickness allows the solar cell 80 to excel both in the electric power generation efficiency and the mechanical characteristics. The thus set thickness can also contribute to reduction in the thickness of the electronic timepiece 200.

### Method for Manufacturing Solar Cell

A photoelectric conversion device manufacturing method according to an embodiment of the invention will next be described.

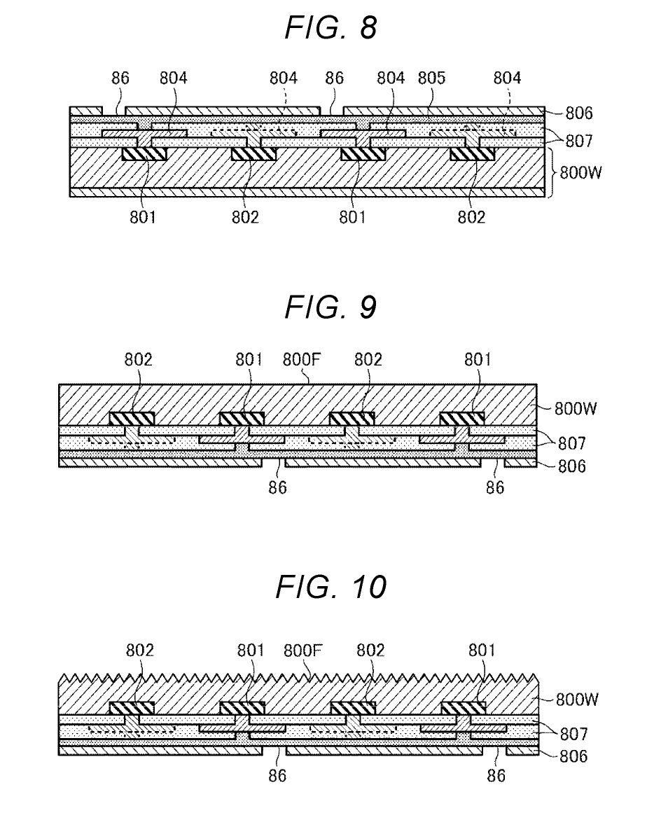

FIGS. 8 to 14 describe the photoelectric conversion device manufacturing method according to the embodiment of the invention. A method for manufacturing the solar cell 80 shown in FIG. 7 will be described by way of example.

The photoelectric conversion device manufacturing method according to the present embodiment includes at least the step of preparing a crystalline semiconductor wafer, the step of forming electrodes and electrode pads on the semiconductor wafer, and the step of performing laser processing on the semiconductor wafer to cut semiconductor substrates (cells) each having an outer edge at least partially formed of a curve and an inner edge at least partially formed of a curve along the outer edge. Semiconductor substrates (cells) suitable for the electronic timepiece 200 can thus be efficiently manufactured. The steps described above will be sequentially described below.

[1] A semiconductor wafer 800W is first prepared. The semiconductor wafer 800W is used as a base material off which a plurality of cells are eventually cut.

[2] The p+ diffused regions 801 and the n+ diffused regions 802 are then formed on one principal surface which is a mirror surface of the semiconductor wafer 800W (see FIG. 8). The p+ diffused regions 801 and the n+ diffused regions 802 are formed, for example, by injecting impurity ions into the semiconductor wafer 800W and then causing the resultant semiconductor wafer 800W to undergo activating annealing.

The finger electrodes 804, the bus bar electrode 805, the passivation films 806, and the interlayer insulating film 807 are subsequently formed on the semiconductor wafer 800W (see FIG. 8). The finger electrodes 804 and the bus bar electrode 805 are each formed by depositing an electrically conductive material, for example, in any of a variety of evaporation methods and then patterning the resultant coating. The passivation films 806 and the interlayer insulating film 807 are each formed by depositing an insulating material, for example, in any of a variety of evaporation methods and then patterning the resultant coating.

[3] A surface 800F of the semiconductor wafer 800W, the surface on the side opposite the principal surface on which the electrodes and the like described above have been formed, is then polished (see FIG. 9). A clean surface of the semiconductor material is thus exposed.

[4] The texture is then formed on the surface 800F of the semiconductor wafer 800W (see FIG. 10). The texture is formed, for example, by using a wet etching method.

A passivation film and an antireflection film that are not shown are then formed as required on the surface 800F.

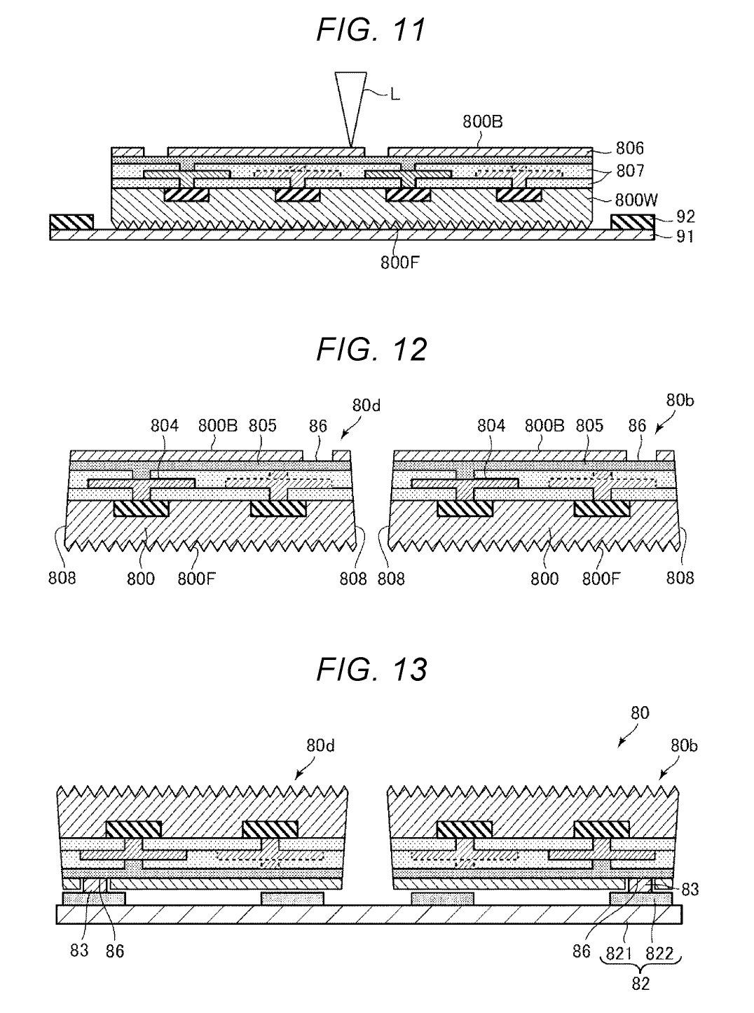

A heating process (sinter process) is then carried out as required. The characteristics of the semiconductor wafer 800W can thus be optimized.

[5] The surface 800F of the semiconductor wafer 800W is then attached to an adhesive tape 91. A dicing ring 92 attached to an outer circumferential portion of the adhesive tape 91 readily supports the adhesive tape 91 and the semiconductor wafer 800W attached thereto.

[6] A rear surface 800B of the semiconductor wafer 800W is then irradiated with a laser beam L for the laser processing. That is, a surface of the semiconductor wafer 800W that is the surface on which the finger electrodes 804, the bus bar electrode 805, and the electrode pads 86 have been formed is irradiated with the laser beam L for the laser processing (see FIG. 11). A plurality of cells 80b and 80d are thus cut off the semiconductor wafer 800W (see FIG. 12).

The thus cut cells 80b and 80d are each formed of an outer edge at least partially formed of a curve and an inner edge at least partially formed of a curve along the outer edge, as described above.

The cut surfaces of the semiconductor wafer 800W reflect a phenomenon in which the kerf (width of cut groove) closer to a light source that emits the laser beam L is wider and the kerf farther to the light source is narrower. The end surfaces 808 of the cells 80b and 80d cut in the laser-processing cutting are therefore each an inclining surface that inclines in such a way that the surface 800F overhangs beyond the rear surface 800B, as shown in FIG. 12. That is, the end surfaces 808 are each an inclining surface that inclines in such a way that the surface that forms the light receiving surface overhangs beyond the surface on which the electrode pads and the like have been formed and which is opposite the light receiving surface.

In the laser processing, the surface 800F of the semiconductor wafer 800W can be protected by the adhesive tap attached to the surface 800F. A situation in which byproducts produced in the laser processing (vaporized substances and scattered substances) contaminate the surface 800F can thus be avoided.

Cleaning is then performed as required.

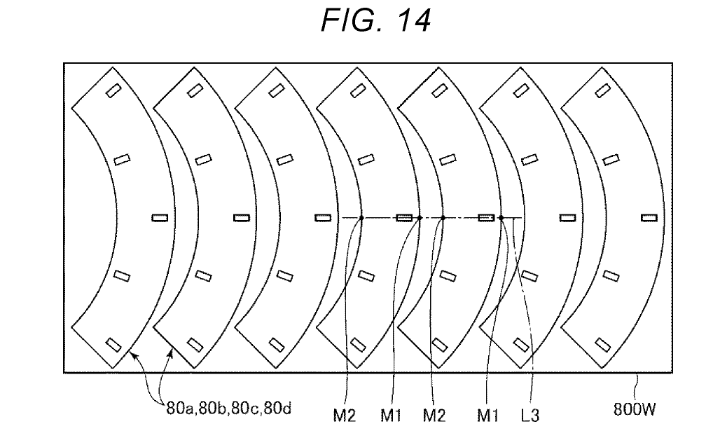

FIG. 14 shows an example of a cutting pattern in accordance with which the cells 80a, 80b, 80c, and 80d described above are cut. The cutting pattern shown in FIG. 14 is a pattern that allows a straight line L3, which connects a midpoint M1 of the outer edge of one cell to the midpoint M2 of the inner edge thereof, to be so drawn that the midpoints M1 and M2 of the remaining cells are located on the straight line L3. Employing the cutting pattern described above allows the cells to cut with the marginal area reduced.

According to the cutting pattern described above, the crystal orientations of the four cells 80a, 80b, 80c, and 80d are naturally equivalent to one another. Arranging the four cells 80a, 80b, 80c, and 80d in such a way that they are 90° rotationally symmetric with respect to the center C as the axis of rotation of the symmetry as shown in FIG. 3 therefore allows the notable exterior design described above to be achieved.

[7] The electrode pads 86 and the wiring substrate 82 are then connected to each other via the electrically conductive connection sections 83. The solar cell 80 (solar cell module) is thus produced (see FIG. 13).

The invention has been described above based on the illustrated embodiments, but the invention is not limited thereto.

For example, the electronic apparatus according to the embodiment of the invention may be so configured that part of the elements in the embodiment described above is replaced with an arbitrary element having the same function or an arbitrary element is added to the embodiment described above.

In the photoelectric conversion device manufacturing method according to the embodiment of the invention, an arbitrary step may be added to the embodiment described above.

The entire disclosure of Japanese Patent Application No. 2017-230036, filed Nov. 30, 2017 is expressly incorporated by reference herein.

What is claimed is:

1. An electronic apparatus comprising:
a case having an opening including a curve; and
a photoelectric conversion device that is provided in the case and includes a crystalline semiconductor substrate, the photoelectric conversion having an outer edge that includes at least partially formed of an outer curve portion along the opening, and the photoelectric conversion having an inner edge that includes at least partially formed of an inner curve portion along the outer edge.

2. The electronic apparatus according to claim 1, wherein
the inner edge has a first virtual point and a second virtual point,
the first virtual point has a first virtual perpendicular and the second virtual point has a second virtual perpendicular, and
the first virtual perpendicular intersects with the second virtual perpendicular in the opening.

3. The electronic apparatus according to claim 1,
wherein the photoelectric conversion device includes a plurality of electrode pads, and
the plurality of electrode pads are arranged along the outer or inner edge of the photoelectric conversion device.

4. The electronic apparatus according to claim 1, further comprising an electrooptical panel having an outer shape along the inner edge of the photoelectric conversion device.

5. The electronic apparatus according to claim 1,
wherein the photoelectric conversion device has an annular shape.

6. The electronic apparatus according to claim 1, further comprising an electrooptical panel,
wherein at least part of the photoelectric conversion device is so disposed as to overlap with a region outside a pixel region of the electrooptical panel.

7. The electronic apparatus according to claim 1,
wherein the semiconductor substrate is a single-crystal semiconductor substrate.

8. The electronic apparatus according to claim 7,
wherein the photoelectric conversion device includes a plurality of the semiconductor substrates, and
the plurality of the semiconductor substrates have the same crystal orientation.

9. The electronic apparatus according to claim 7,
wherein a concentration of an impurity element other than a primary constituent element of the semiconductor substrate is lower than or equal to 1×10¹¹ [atoms/cm²].

10. The electronic apparatus according to claim 8,
wherein a concentration of an impurity element other than a primary constituent element of the semiconductor substrate is lower than or equal to 1×10¹¹ [atoms/cm²].

11. The electronic apparatus according to claim 1,
wherein at least part of an end surface of the photoelectric conversion device is so configured that a light receiving surface overhangs beyond a rear surface.
